(19) United States
(12) Patent Application Publication
(10) Pub. No.: US 2014/0210521 A1
(43) Pub. Date: Jul. 31, 2014

(54) GATE OR SOURCE DRIVING APPARATUS

(71) Applicant: Novatek Microelectronics Corp., Hsinchu (TW)

(72) Inventors: Chih-Yuan Hsieh, Hsinchu County (TW); Tsung-Yin Yu, Yilan County (TW); Jie-Jung Huang, Miaoli County (TW)

(73) Assignee: Novatek Microelectronics Corp., Hsinchu (TW)

(21) Appl. No.: 14/054,854

(22) Filed: Oct. 16, 2013

(30) Foreign Application Priority Data
Jan. 28, 2013 (TW) 102103182

(51) Int. Cl. H03K 3/01

(52) U.S. Cl. CPC H03K 3/01
USPC 327/108

(57) ABSTRACT

A gate/source driving apparatus includes a first gate/source driving chip and a second gate/source driving chip. The first gate/source driving chip includes a plurality of first charge pump circuits, each of which has a voltage input end, a voltage output end, a first capacitor end, and a second capacitor end. The second gate/source driving chip includes a plurality of second charge pump circuits, each of which also has a voltage input end, a voltage output end, a first capacitor end, and a second capacitor end. The voltage output end of at least one of the first charge pump circuits is coupled to the voltage input end of at least one of the second charge pump circuits.

### CROSS-REFERENCE TO RELATED APPLICATION

This application claims the priority benefit of Taiwan application serial no. 102103182, filed on Jan. 28, 2013. The entirety of the above-mentioned patent application is hereby incorporated by reference herein and made a part of this specification.

### BACKGROUND OF THE INVENTION

1. Field of the Invention

The invention relates to a gate or source driving apparatus. More particularly, the invention relates to a method of applying charge pump circuits in a gate or source driving apparatus.

2. Description of Related Art

Nowadays, given that a display apparatus (e.g., a liquid crystal display (LCD) apparatus) with a large panel is to be driven, a number of driving chips are often required. In the conventional LCD apparatus, required power supply circuits are often integrated into the driving chips, so as to raise the integration level. For instance, it is assumed that one driving chip includes N charge pump circuits as the power supply circuits, and when the LCD apparatus is equipped with M driving chips, the LCD apparatus may have N×M charge pump circuits. Here, N and M are integers greater than 1.

However, the operating voltage generated by the power supply circuits required by the LCD apparatus has the constant value; therefore, a sufficient number of charge pump circuits in the conventional LCD apparatus are selected to perform a voltage multiplying process and thereby generate the operating voltage required by the LCD apparatus, whereas the non-selected charge pump circuits are left unused. This leads to significant waste of resources and deterioration of utilization efficiency of the LCD apparatus.

### SUMMARY OF THE INVENTION

The invention is directed to a gate/source driving apparatus which effectively applies charge pump circuits of gate/source driving chips to improve the efficiency of the gate/source driving apparatus.

In an embodiment of the invention, a gate/source driving apparatus that includes a first gate/source driving chip and a second gate/source driving chip is provided. The first gate/source driving chip includes a plurality of first charge pump circuits, each of which has a voltage input end, a voltage output end, a first capacitor end, and a second capacitor end. The second gate/source driving chip includes a plurality of second charge pump circuits, each of which also has a voltage input end, a voltage output end, a first capacitor end, and a second capacitor end. The voltage output end of at least one of the first charge pump circuits is coupled to the voltage input end of at least one of the second charge pump circuits.

As discussed above, the charge pump circuits of different gate/source driving chips in the gate/source driving apparatus are connected at least in a serial manner, so as to fully apply the charge pump circuits of the gate/source driving chips and thereby ameliorate the utilization efficiency of the gate/source driving apparatus. In an embodiment of the invention, the charge pump circuits of different gate/source driving chips are connected in parallel, and the charge pump circuits of the same gate/source driving chip are connected in series and/or in parallel. Thereby, all of the charge pump circuits in the gate or source driving apparatus may be fully utilized, and the work efficiency of the gate or source driving apparatus may be improved.

Several exemplary embodiments accompanied with figures are described in detail below to further describe the invention in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the invention.

FIG. 1A to FIG. 6 are schematic diagrams illustrating a gate/source driving apparatus according to several embodiments of the invention.

### DETAILED DESCRIPTION OF DISCLOSED EMBODIMENTS

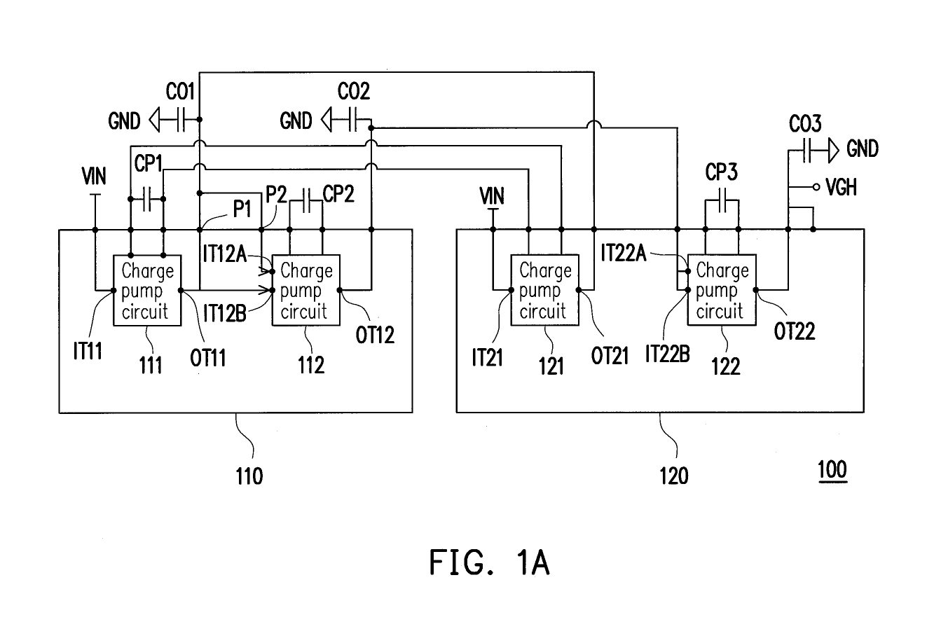

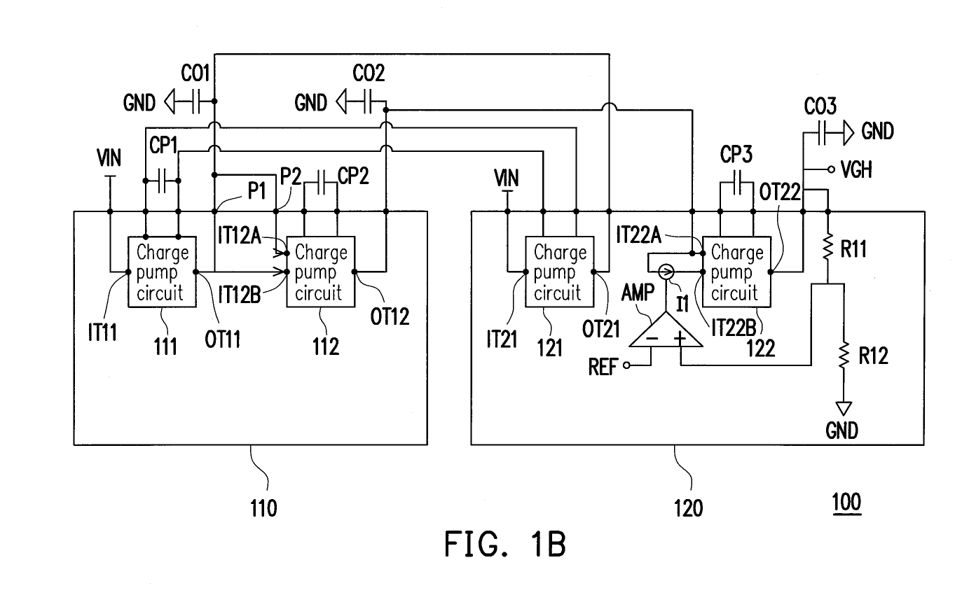

Please refer to FIG. 1A that schematically illustrates a gate/source driving apparatus 100 according to an embodiment of the invention. The gate/source driving apparatus 100 includes gate/source driving chips 110 and 120. The gate/source driving chip 110 includes charge pump circuits 111 and 112, and the gate/source driving chip 120 includes charge pump circuits 121 and 122. The charge pump circuit 111 has a voltage input end IT11, a voltage output end OT11, and two capacitor ends that are respectively connected to two ends of a capacitor CP1. The charge pump circuit 112 has a voltage input end IT12, a voltage output end OT12, and two capacitor ends that are respectively connected to two ends of a capacitor CP2. The charge pump circuit 121 has a voltage input end IT21 and a voltage output end OT21, and the charge pump circuit 122 has a voltage input end IT22 and a voltage output end OT22. Two capacitor ends of the charge pump circuit 121 are respectively connected to the two ends of the capacitor CP1, and two capacitor ends of the charge pump circuit 122 are respectively connected to two ends of a capacitor CP3.

Note that the voltage output end (e.g., the voltage output end OT12) of at least one of the charge pump circuits (e.g., the charge pump circuit 112) in the gate/source driving chip 110 is coupled to the voltage input end (e.g., the voltage input end IT22A) of at least one of the charge pump circuits (e.g., the charge pump circuit 122) in the gate/source driving chip 120. That is, at least one set of the charge pump circuits respectively in the gate/source driving chips 110 and 120 is coupled in series. Thereby, the charge pump circuits in the gate/source driving chips 110 and 120 may all be effectively applied.

In addition, according to the present embodiment, the charge pump circuits 111 and 112 in the gate/source driving chip 110 are connected in series. Specifically, the voltage input end IT11 of the charge pump circuit 111 receives an input voltage VIN, and the voltage output end OT11 of the charge pump circuit 111 is coupled to the voltage input end IT12A of the charge pump circuit 112 through pads P1 and P2 on the gate/source driving chip 110. In addition, the voltage output end OT11 of the charge pump circuit 111 is also connected to the voltage input end IT12B of the charge pump circuit 112 through conductive wires in the gate/source driving chip 110. If the charge pump circuit 111 is used for doubling the input voltage, the voltage on the voltage output end of this exemplary charge pump circuit is twice the input voltage VIN. In addition, the voltage output end OT 12 of the charge pump circuit 112 generates a voltage equal to the sum of the voltages on the voltage input ends IT12A and IT12B; that is, the voltage output end OT12 of the charge pump circuit 112 generates a voltage four times the input voltage VIN. The voltage input end IT21 of the charge pump circuit 121 in the gate/source driving chip 120 receives the input voltage VIN, and the capacitor ends of the charge pump circuit 121 are correspondingly connected to the capacitor ends of the charge pump circuit 111 in the gate/source driving chip 110. Here, the charge pump circuit 121 serves to generate a parallel connection effect together with the charge pump circuit 111 in the gate/source driving chip 110, reduce output impedance of the charge pump circuit 111, and improve the voltage multiplying efficiency of the charge pump circuit 111. The charge pump circuit 122 in the gate/source driving chip 120 is serially connected to the charge pump circuit 112 in the gate/source driving chip 110. Namely, the voltage output end OT12 of the charge pump circuit 112 is coupled to the voltage input end IT22A of the charge pump circuit 122. Thereby, given that the voltage on the voltage output end OT12 of the charge pump circuit 112 is four times the input voltage VIN, the voltage on the voltage output end OT22 of the charge pump circuit 122 is eight times the input voltage VIN after the charge pump circuit 122 performs a voltage multiplying process.

As a result, the gate/source driving apparatus 100 generates a gate or source driving voltage VGH which is eight times the input voltage VIN.

It may be deduced from the above that all of the charge pump circuits 111, 112, 121, and 112 in the gate/source driving chips 110 and 120 may be effectively applied, and thus the work efficiency of the gate/source driving apparatus 100 may be improved.

Besides, the voltage output ends OT11, OT12, and OT22 of the charge pump circuits 111, 112, and 122 are respectively coupled to voltage regulating capacitors CO1, CO2, and CO3. The other ends of the voltage regulating capacitors CO1, CO2, and CO3 are coupled to a reference voltage GND. The reference voltage GND may be a ground voltage.

Please refer to FIG. 1B that schematically illustrates the gate/source driving apparatus 100 according to another embodiment of the invention. In FIG. 1B, the voltage input ends IT22A and IT22B of the charge pump circuit 122 in the gate/source driving apparatus 100 are not directly coupled to each other. A power source Il serially connects the voltage input ends IT22A and IT22B, and a current generated by the power source I1 is controlled by the output of an amplifier AMP. A negative input end of the amplifier AMP receives the reference voltage GND, and the voltage received by a positive input end of the amplifier AMP is generated by dividing the gate/source driving voltage VGH. The voltage dividing process is performed by resistors R1 and R2 that serially connect the gate/source driving voltage VGH and the reference voltage GND.

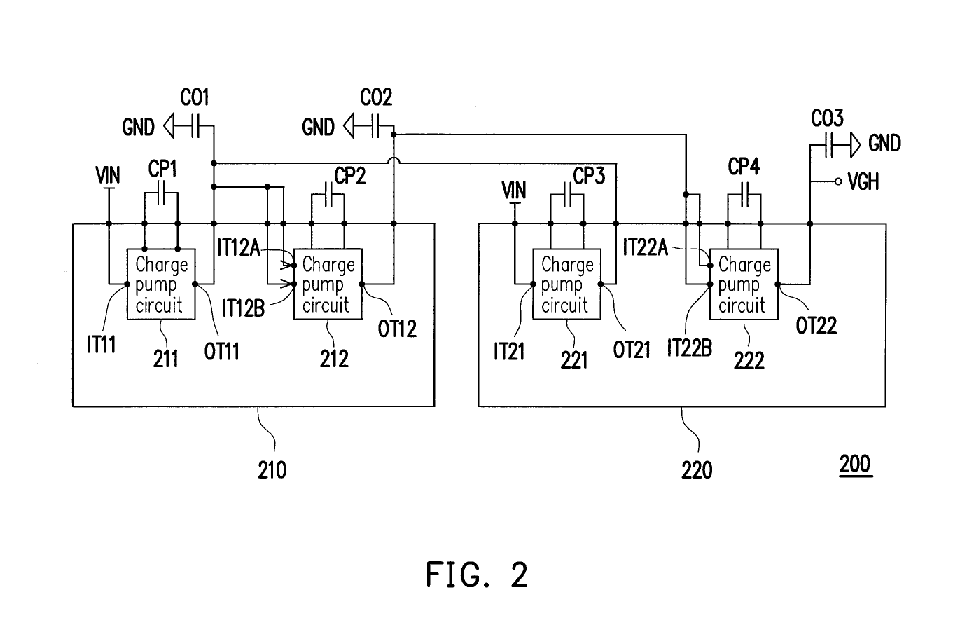

Please refer to FIG. 2 that schematically illustrates a gate/source driving apparatus 200 according to another embodiment of the invention. The gate/source driving apparatus 200 includes gate/source driving chips 210 and 220. The gate/source driving chip 210 includes charge pump circuits 211 and 212, and the gate/source driving chip 220 includes charge pump circuits 221 and 222. In the present embodiment, capacitor ends of the charge pump circuits 211 and 212 are respectively coupled to capacitors CP1 and CP2, and capacitor ends of the charge pump circuits 221 and 222 are respectively coupled to capacitors CP3 and CP4. The voltage input end IT11 of the charge pump circuit 211 receives the input voltage VIN, and the voltage output end OT11 of the charge pump circuit 211 is coupled to the voltage input ends IT12A and IT12B of the charge pump circuit 212. The charge pump circuit 211 serves to perform a voltage multiplying process on the input voltage VIN and transmit the voltage (twice the input voltage VIN) to the charge pump circuit 212. The charge pump circuit 212 adds the voltage (twice the input voltage VIN) received by its voltage input end IT12A to the voltage (twice the input voltage VIN) received by its voltage input end IT12B and generates a voltage (four times the input voltage VIN) at its voltage output end OT12.

The voltage output end OT12 of the charge pump circuit 222 is coupled to the voltage input ends IT22A and IT22B of the charge pump circuit 222. The charge pump circuit 222 adds the voltage (four times the input voltage VIN) received by its voltage input end IT22A to the voltage (four times the input voltage VIN) received by its voltage input end IT22B and generates a voltage (eight times the input voltage VIN) at its voltage output end OT22. The voltage (eight times the input voltage VIN) acts as the gate/source driving voltage VGH.

The voltage input end IT21 of the charge pump circuit 221 receives the input voltage VIN, and the voltage output end OT21 of the charge pump circuit 221 is coupled to the voltage output end OT11 of the charge pump circuit 211. That is, the charge pump circuits 221 and 211 are connected in parallel, and their reference clock signals may be in-phase signals or out-of-phase signals. Thereby, the voltage multiplying process performed on the input voltage VIN may be accelerated effectively, and the step of generating a voltage twice the input voltage VIN may be expedited.

Note that the capacitors ends of the charge pump circuits 211, 212, 221, and 222 are respectively coupled to the capacitors CP1, CP2, CP3, and CP4. Besides, the voltage output ends OT11, OT12, and OT22 of the charge pump circuits 211, 212, and 222 are respectively coupled to voltage regulating capacitors CO1, CO2, and CO3.

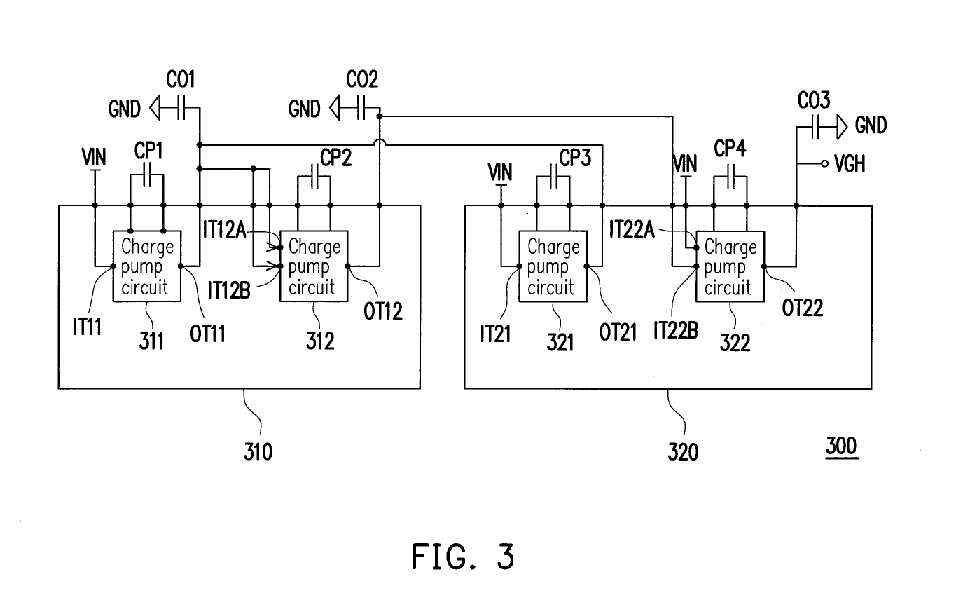

Please refer to FIG. 3 that schematically illustrates a gate/source driving apparatus 300 according to still another embodiment of the invention. The gate/source driving apparatus 300 includes gate/source driving chips 310 and 320. The gate/source driving chip 310 includes charge pump circuits 311 and 312, and the gate/source driving chip 320 includes charge pump circuits 321 and 322. The voltage input end IT11 of the charge pump circuit 311 receives the input voltage VIN, and the voltage output end OT11 of the charge pump circuit 311 is coupled to the voltage input ends IT12A and IT12B of the charge pump circuit 312. In addition, the voltage output end OT11 of the charge pump circuit 311 provides a voltage (twice the input voltage VIN) to the voltage input ends IT12A and IT12B of the charge pump circuit 312. The voltage output end OT12 of the charge pump circuit 312 generates a voltage four times the input voltage VIN.

The voltage output end OT12 of the charge pump circuit 312 is coupled to the voltage input end IT22B of the charge pump circuit 322. The other voltage input end IT22A of the charge pump circuit 322 receives the input voltage VIN. The charge pump circuit 322 generates a voltage (five times the input voltage VIN) at its voltage output end OT22 and provides such a voltage as the gate/source driving voltage VGH.

The voltage input end IT21 of the charge pump circuit 321 receives the input voltage VIN, and the voltage output end OT21 of the charge pump circuit 321 is coupled to the voltage output end OT11 of the charge pump circuit 311, such that the charge pump circuits 321 and 311 are connected in parallel.

Note that the capacitors ends of the charge pump circuits 311, 312, 321, and 322 are respectively coupled to the capacitors CP1, CP2, CP3, and CP4. Besides, the voltage output ends OT11, OT12, OT21, and OT22 of the charge pump circuits 311, 312, 321, and 322 are respectively coupled to first ends of voltage regulating capacitors CO1, CO2, CO1, and CO3. The second ends of the voltage regulating capacitors CO1, CO2, and CO3 are coupled to the reference voltage GND.

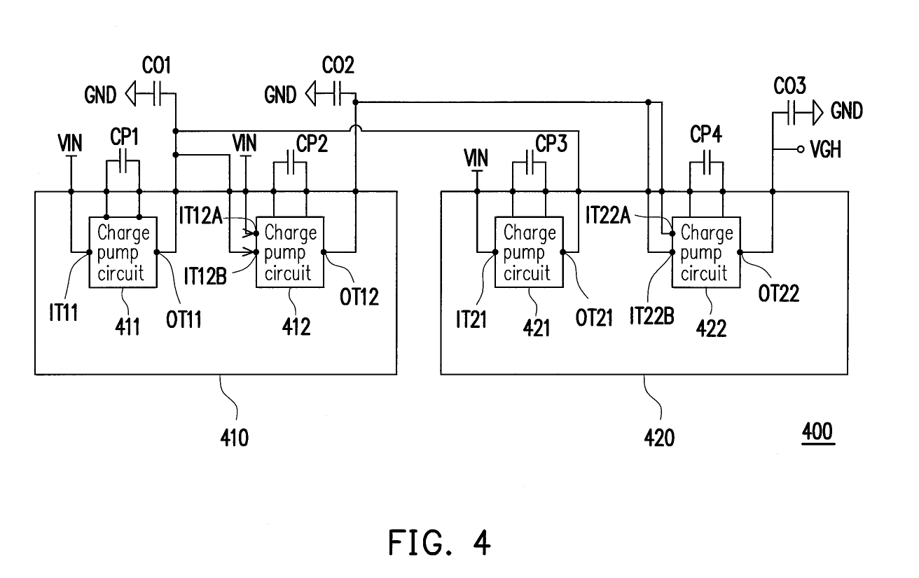

Please refer to FIG. 4 that schematically illustrates a gate/source driving apparatus 400 according to still another embodiment of the invention. The gate/source driving apparatus 400 includes gate/source driving chips 410 and 420. The gate/source driving chip 410 includes charge pump circuits 411 and 412, and the gate/source driving chip 420 includes charge pump circuits 421 and 422. In an embodiment of the invention, the voltage input end IT11 of the charge pump circuit 411 receives the input voltage VIN, and the voltage output end OT11 of the charge pump circuit 411 is coupled to the voltage input end IT12B of the charge pump circuit 412. In addition, the voltage output end OT11 of the charge pump circuit 411 provides a voltage (twice the input voltage VIN) to the voltage input end IT12B of the charge pump circuit 412. The other voltage input end IT12A of the charge pump circuit 412 receives the input voltage VIN. The voltage output end OT12 of the charge pump circuit 412 generates a voltage three times the input voltage VIN.

The voltage output end OT12 of the charge pump circuit 412 is coupled to the voltage input ends IT22A and IT22B of the charge pump circuit 422. The charge pump circuit 422 generates a voltage (sixth times the input voltage VIN) at its voltage output end OT22 and provides such a voltage as the gate/source driving voltage VGH.

The voltage input end IT21 of the charge pump circuit 421 receives the input voltage VIN, and the voltage output end OT21 of the charge pump circuit 421 is coupled to the voltage output end OT11 of the charge pump circuit 411, such that the charge pump circuits 421 and 411 are connected in parallel.

Note that the capacitors ends of the charge pump circuits 411, 412, 421, and 422 are respectively coupled to the capacitors CP1, CP2, CP3, and CP4. Besides, the voltage output ends OT11, OT12, OT21, and OT22 of the charge pump circuits 411, 412, 421, and 422 are respectively coupled to first ends of voltage regulating capacitors CO1, CO2, CO1, and CO3. The second ends of the voltage regulating capacitors CO1, CO2, and CO3 are coupled to the reference voltage GND.

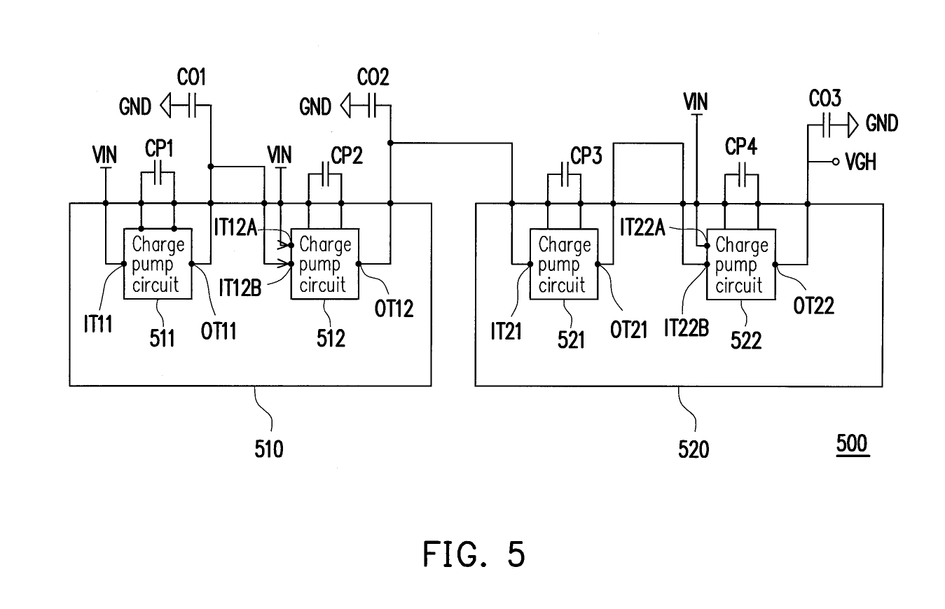

Please refer to FIG. 5 that schematically illustrates a gate/source driving apparatus 500 according to still another embodiment of the invention. The gate/source driving apparatus 500 includes gate/source driving chips 510 and 520. The gate/source driving chip 510 includes charge pump circuits 511 and 512, and the gate/source driving chip 520 includes charge pump circuits 521 and 522. In an embodiment of the invention, the voltage input end IT11 of the charge pump circuit 511 receives the input voltage VIN, and the voltage output end OT11 of the charge pump circuit 511 is coupled to the voltage input end IT12B of the charge pump circuit 512. In addition, the voltage output end OT11 of the charge pump circuit 511 provides a voltage (twice the input voltage VIN) to the voltage input end IT12B of the charge pump circuit 512. The other voltage input end IT12A of the charge pump circuit 512 receives the input voltage VIN. The voltage output end OT12 of the charge pump circuit 512 generates a voltage three times the input voltage VIN.

The voltage output end OT12 of the charge pump circuit 512 is coupled to the voltage input end IT21 of the charge pump circuit 521. The voltage output end OT22 of the charge pump circuit 521 generates a voltage six times the input voltage VIN. The voltage output end OT21 of the charge pump circuit 521 is coupled to the voltage input end IT22B of the charge pump circuit 522, and the other voltage input end of the charge pump circuit 522 receives the input voltage VIN. The voltage output end OT22 of the charge pump circuit 522 generates a voltage seven times the input voltage VIN, and such a voltage serves as the gate/source driving voltage VGH.

Note that the capacitors ends of the charge pump circuits 511, 512, 521, and 522 are respectively coupled to the capacitors CP1, CP2, CP3, and CP4. Besides, the voltage output ends OT11, OT12, and OT22 of the charge pump circuits 511, 512, and 522 are respectively coupled to first ends of voltage regulating capacitors CO1, CO2, and CO3. The second ends of the voltage regulating capacitors CO1, CO2, and CO3 are coupled to the reference voltage GND.

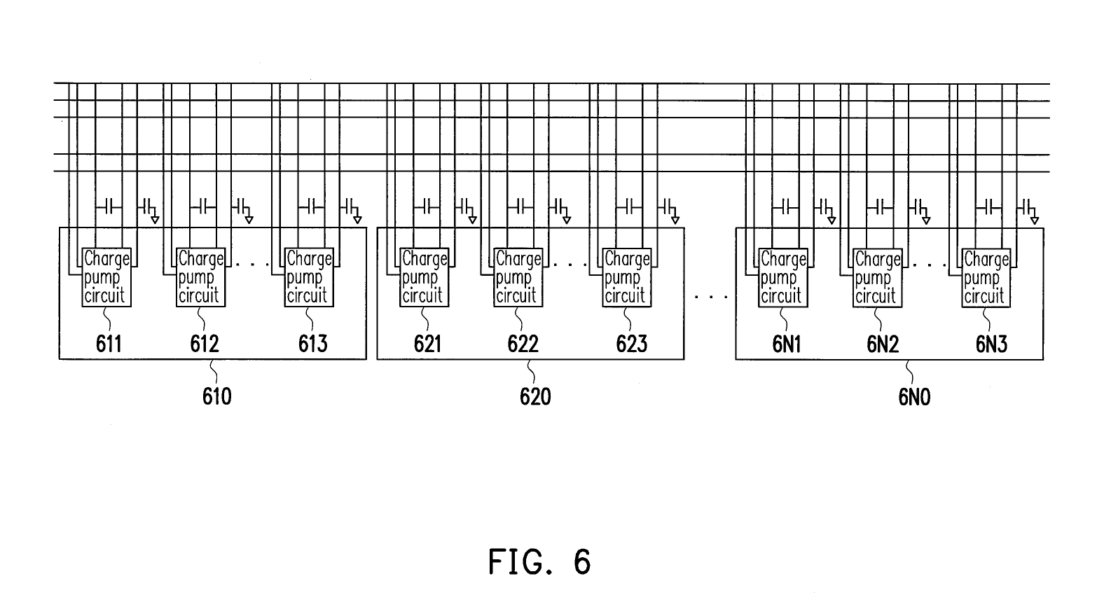

Please refer to FIG. 6 that schematically illustrates a gate/source driving apparatus 600 according to still another embodiment of the invention. As shown in FIG. 6, the gate/source driving apparatus 600 utilizes a plurality of integrated circuits 610 to 6N0 that are connected in series and/or in parallel, so as to effectively improve the resultant gate/source driving voltage. In the present embodiment, the charge pump circuits 611 to 613, 621 to 623, and 6N1 to 6N3 respectively in the integrated circuits 610 to 6N0 are all applied effectively, such that costs required by the circuits may be lowered down.

To sum up, in the gate/source driving apparatus, at least one charge pump circuit of the first gate/source driving chip and at least one charge pump circuit of the second gate/source driving chip are serially connected, and thereby the charge pump circuits in the first and second gate/source driving chips may all function effectively. In an embodiment of the invention, the serial and/or parallel connection of the same and/or different charge pump circuits allows the input voltage to be multiplied by different multiples, so as to generate the required gate/source driving voltage. Moreover, the charge pump circuits in all of the gate/source driving chips are effectively applied, and so are the circuitry resources therein. Accordingly, the work performance of the gate/source driving apparatus is enhanced.

It will be apparent to those skilled in the art that various modifications and variations can be made to the structure of the disclosed embodiments without departing from the scope or spirit of the invention. In view of the foregoing, it is intended that the invention cover modifications and variations of this invention provided they fall within the scope of the following claims and their equivalents.

What is claimed is:

1. A gate/source driving apparatus comprising:
a first gate/source driving chip comprising a plurality of first charge pump circuits, each of the first charge pump circuits having a voltage input end, a voltage output end, a first capacitor end, and a second capacitor end; and
a second gate/source driving chip comprising a plurality of second charge pump circuits, each of the second charge pump circuits having a voltage input end, a voltage output end, a first capacitor end, and a second capacitor end,
wherein the voltage output end of at least one of the first charge pump circuits is coupled to the voltage input end of at least one of the second charge pump circuits.

2. The gate/source driving apparatus as recited in claim 1, wherein parts of the first charge pump circuits are coupled in parallel, the voltage input ends of the parts of the first charge pump circuits are coupled, and the voltage output ends of the parts of the first charge pump circuits are coupled.

3. The gate/source driving apparatus as recited in claim 2, wherein the first capacitor ends of the parts of the first charge pump circuits are collectively coupled to a first end of a capacitor, and the second capacitor ends of the parts of the first charge pump circuits are collectively coupled to a second end of the capacitor.

4. The gate/source driving apparatus as recited in claim 1, wherein at least one of the first charge pump circuits is coupled in parallel to at least one of the second charge pump circuits, the voltage output ends of the at least one of the first charge pump circuits and the at least one of the second charge pump circuits coupled in parallel are coupled, and the voltage input ends of the at least one of the first charge pump circuits and the at least one of the second charge pump circuits coupled in parallel are coupled.

5. The gate/source driving apparatus as recited in claim 4, wherein the first capacitor ends of the at least one of the first charge pump circuits and the at least one of the second charge pump circuits coupled in parallel are collectively coupled to a first end of a capacitor, and the second capacitor ends of the at least one of the first charge pump circuits and the at least one of the second charge pump circuits coupled in parallel are collectively coupled to a second end of the capacitor.

6. The gate/source driving apparatus as recited in claim 1, wherein parts of the first charge pump circuits are coupled in parallel, and the voltage output end of each of the parts of the first charge pump circuits is coupled to the voltage input end of one of the first charge pump circuits adjacent to the each of the parts of the first charge pump circuits.

7. The gate/source driving apparatus as recited in claim 1, wherein parts of the second charge pump circuits are coupled in parallel, and the voltage output end of each of the parts of the second charge pump circuits is coupled to the voltage input end of one of the second charge pump circuits adjacent to the each of the parts of the second charge pump circuits.

8. The gate/source driving apparatus as recited in claim 1 further comprising:
a plurality of voltage regulating capacitors serially connecting the voltage output ends of the first and second charge pump circuits and a reference voltage, respectively.

9. The gate/source driving apparatus as recited in claim 1 further comprising:
a plurality of capacitors serially connecting the first capacitor ends of the first and second charge pump circuits and the second capacitor ends of the first and second charge pump circuits, respectively.

10. The gate/source driving apparatus as recited in claim 1, wherein the voltage input end of each of the first and second charge pump circuits receives an input voltage, the voltage output end of each of the first and second charge pump circuits generates an output voltage, the output voltage is P times the input voltage, and P is an integer greater than 1.

11. The gate/source driving apparatus as recited in claim 1, wherein the first charge pump circuits receive a first clock signal and perform a voltage multiplying process according to the first clock signal, and the second charge pump circuits receive a second clock signal and perform a voltage multiplying process according to the second clock signal.

12. The gate/source driving apparatus as recited in claim 1, wherein the voltage input end of each of parts of the first and second charge pump circuits receives a first input voltage and a second input voltage, and the voltage output end of each of the first charge pump circuits generates an output voltage equal to a sum of the first input voltage and the second input voltage.
